(19) United States
(12) Patent Application Publication
(10) Pub. No.: US 2026/0076101 A1
(43) Pub. Date: Mar. 12, 2026

(54) AREA-SELECTIVE JOSEPHSON JUNCTION TUNNEL BARRIER FORMATION AND QUBIT CAP INTEGRATION

(71) Applicant: Tokyo Electron Limited, Tokyo (JP)

(72) Inventors: Hunter FROST, Albany, NY (US); Ryota YONEZAWA, Albany, NY (US)

(73) Assignee: Tokyo Electron Limited, Tokyo (JP)

(21) Appl. No.: 18/830,058

(22) Filed: Sep. 10, 2024

(51) Int. Cl. H10N 60/01; H10N 60/12; H10N 60/85

(52) U.S. Cl. CPC H10N 60/0912; H10N 60/12; H10N 60/85

(57) ABSTRACT

A method of manufacturing a semiconductor device is provided. The method includes forming an opening in a sacrificial layer to expose a first superconducting electrode below the sacrificial layer. An inhibitor film is formed selectively on the sacrificial layer while leaving the first superconducting electrode exposed. A tunnel barrier is formed on the first superconducting electrode. A second superconducting electrode is formed on the tunnel barrier. The sacrificial layer is removed to expose a sidewall of the second superconducting electrode. A capping layer is formed on the sidewall of the second superconducting electrode.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Complementary metal-oxide-semiconductor (CMOS) is a type of metal-oxide-semiconductor field-effect transistor (MOSFET) fabrication process that uses complementary and symmetrical pairs of p-type and n-type MOSFETs for logic functions. CMOS technology is traditionally used for constructing integrated circuit (IC) chips, including microprocessors, microcontrollers, memory chips (including CMOS BIOS), and other digital logic circuits. CMOS technology is also used for analog circuits such as image sensors (CMOS sensors), data converters, RF circuits (RF CMOS), and highly integrated transceivers for many types of communication. Beyond CMOS refers to the possible future digital logic technologies beyond the scaling limits of CMOS technology, which limit device density and speeds due to heating effects.

### SUMMARY

The present disclosure relates to a semiconductor device and a method of forming the same.

According to a first aspect of the disclosure, a method of manufacturing a semiconductor device is provided. The method includes forming an opening in a sacrificial layer to expose a first superconducting electrode below the sacrificial layer. An inhibitor film is formed selectively on the sacrificial layer while leaving the first superconducting electrode exposed. A tunnel barrier is formed on the first superconducting electrode. A second superconducting electrode is formed on the tunnel barrier. The sacrificial layer is removed to expose a sidewall of the second superconducting electrode. A capping layer is formed on the sidewall of the second superconducting electrode.

In some embodiments, the sacrificial layer and a metal oxide layer are etched through. The metal oxide layer is positioned between the sacrificial layer and the first superconducting electrode.

In some embodiments, after the forming the tunnel barrier, a superconducting material is deposited in the opening, resulting in an overburden of the superconducting material over the sacrificial layer. The overburden of the superconducting material is removed so that a remaining portion of the superconducting material forms the second superconducting electrode.

In some embodiments, the removing the sacrificial layer also exposes a top portion of the first superconducting electrode. The capping layer covers the top surface of the second superconducting electrode and the top portion of the first superconducting electrode.

In some embodiments, the first superconducting electrode and the second superconducting electrode each independently include one selected from the group consisting of an elemental superconducting metal, a superconducting alloy and a superconducting nitride.

In some embodiments, the elemental superconducting metal includes niobium (Nb), tantalum (Ta), aluminum (Al) or a combination thereof. The superconducting alloy includes NbTi, WSi or a combination thereof. The superconducting nitride includes NbN.

In some embodiments, the inhibitor film includes one selected from the group consisting of a halogen-containing silane, a boron-containing molecule, a nitrogen-containing silane and an organic molecule.

In some embodiments, the halogen-containing silane includes methyltrichlorosilane, dimethyldichlorosilane, chlorotrimethylsilane, ethyltrichlorosilane, butyl trichlorosilane, octyl trichlorosilane, dodecyl trichlorosilane, octadecyl trichlorosilane or a combination thereof. The boron-containing molecule includes (dimethylphenylsilyl)boronic acid pinacol ester. The nitrogen-containing silane includes N,N-dimethyltrimethylsilylamine (TMSDMA). The organic molecule includes pyridine.

In some embodiments, the tunnel barrier includes one selected from the group consisting of a non-superconducting metal nitride, a non-superconducting metal oxide and a non-superconducting metal carbide.

In some embodiments, the non-superconducting metal nitride includes tantalum nitride, aluminum nitride or a combination thereof. The non-superconducting metal oxide includes tantalum oxide, aluminum oxide or a combination thereof. The non-superconducting metal carbide includes tantalum carbide, aluminum carbide or a combination thereof.

In some embodiments, the capping layer includes one selected from the group consisting of a non-superconducting metal and a non-superconducting nitride.

In some embodiments, the non-superconducting metal includes nickel, copper, cobalt or a combination thereof. The non-superconducting nitride includes tantalum nitride, aluminum nitride or a combination thereof.

In some embodiments, the sacrificial layer includes one selected from the group consisting of silicon oxide, silicon nitride and silicon oxynitride.

In some embodiments, the second superconducting electrode is formed on the tunnel barrier so that the tunnel barrier is completely below the second superconducting electrode.

According to a second aspect of the disclosure, a semiconductor device is provided. semiconductor device includes a first superconducting electrode, a tunnel barrier over the first superconducting electrode, a second superconducting electrode over the tunnel barrier, and a capping layer covering a top surface of the second superconducting electrode and a side surface of the second superconducting electrode.

In some embodiments, the first superconducting electrode and the second superconducting electrode each independently includes one selected from the group consisting of an elemental superconducting metal, a superconducting alloy and a superconducting nitride. The tunnel barrier includes one selected from the group consisting of a non-superconducting metal nitride, a non-superconducting metal oxide and a non-superconducting metal carbide. The capping layer includes one selected from the group consisting of a non-superconducting metal and a non-superconducting nitride.

In some embodiments, the first superconducting electrode and the second superconducting electrode each independently include an elemental superconducting metal. The tunnel barrier includes one selected from the group consisting of a non-superconducting metal nitride, a non-superconducting metal oxide and a non-superconducting metal carbide. The capping layer includes a non-superconducting metal.

In some embodiments, the first superconducting electrode and the second superconducting electrode each independently include niobium, tantalum, aluminum or a combination thereof. The tunnel barrier includes tantalum nitride, aluminum nitride, tantalum oxide, aluminum oxide, tantalum carbide, aluminum carbide or a combination thereof. The capping layer includes nickel, copper, cobalt or a combination thereof.

In some embodiments, the tunnel barrier is completely below the second superconducting electrode.

In some embodiments, the first superconducting electrode is longer than the second superconducting electrode along a first lateral direction. The first superconducting electrode is partially covered by the tunnel barrier and partially covered by the capping layer.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a vertical cross-sectional view of a semiconductor device in accordance with one embodiment of the present disclosure.

FIG. 2 shows a flow chart of a process for manufacturing a semiconductor device, in accordance with some embodiments of the present disclosure.

FIGS. 3, 4, 5, 6, 7, 8, 9 and 10 show vertical cross-sectional views of a semiconductor device at various intermediate steps of manufacturing, in accordance with some embodiments of the present disclosure.

FIG. 11 shows a vertical cross-sectional view of a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As noted in the Background, beyond CMOS refers to potential future digital logic technologies that expand beyond the present CMOS scaling limits. However, beyond CMOS technologies, which include quantum computing with superconducting qubits, face many fabrication/process control challenges. Particularly, sources of decoherence are a big obstacle to large-scale quantum computing involving Josephson junctions.

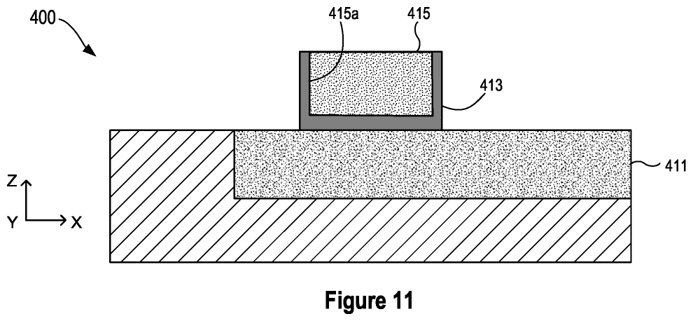

A Josephson junction can be made by sandwiching a thin layer of a non-superconducting material between two layers of superconducting material, also known as the top and bottom superconducting electrodes. This thin layer of the non-superconducting material can be in the form of a tunnel barrier. For example in FIG. 11, a tunnel barrier 413 may exist not only between a top superconducting electrode 415 and a bottom superconducting electrode 411, but also on a sidewall 415a of the top superconducting electrode 415. The tunnel barrier 413, when disposed on the sidewall 415a of the top superconducting electrode 415, can include trap states and/or impurities, therefore contributing to decoherence in Josephson-junction qubits.

Techniques herein utilize an area-selective deposition process to selectively form an inhibitor film on a sacrificial oxide layer while leaving the bottom superconducting electrode exposed for the formation of the tunnel barrier. As a result, the tunnel barrier can be selectively formed between the top and bottom superconducting electrodes. There is no tunnel barrier on the sidewall of the top superconducting electrode. Instead, a capping layer can be formed to cover and protect the sidewall of the top superconducting electrode.

Techniques herein can remove decoherence mechanisms from a non-functional sidewall film and enable protective capping layer integration. Inhibitor molecules are used to selectively grow the tunnel barrier on the underlying metal e.g. the bottom superconducting electrode. Inhibitor removal before the subsequent metal deposition does not need to be perfect as is often required by traditional schemes. Surface oxide removal and capping deposition can further improve coherence and insulate qubits from the environment.

Techniques herein utilize Josephson junction fabrication control to minimize sources of decoherence and utilize simple integration of a protective cap to protect qubit (i.e. quantum bit) architecture from atmospheric exposure and additional decoherence sources. As a result, a major challenge in superconducting qubit fabrication can be eliminated through novel implementation of selective processes. Techniques herein can be readily extended to a variety of material and compositional systems.

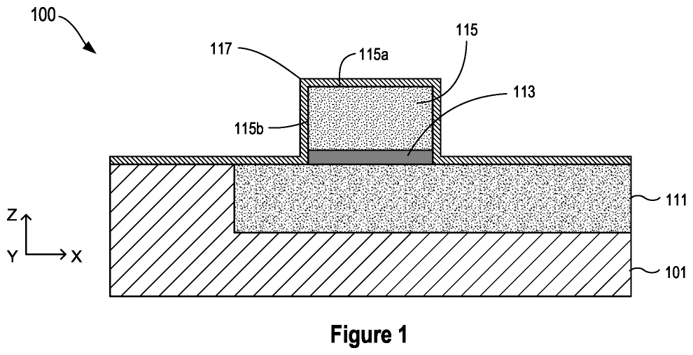

FIG. 1 shows a vertical cross-sectional view of a semiconductor device 100 in accordance with one embodiment of the present disclosure. As illustrated, the semiconductor device 100 includes a base layer 101, a first superconducting electrode 111 (also known as a bottom superconducting electrode) in the base layer 101, a tunnel barrier 113 over the first superconducting electrode 111, a second superconducting electrode 115 (also known as a top superconducting electrode) over the tunnel barrier 113, and a capping layer 117 covering a top surface 115a of the second superconducting electrode 115 and a sidewall 115b of the second superconducting electrode 115. Herein, the tunnel barrier 113 can be completely below the second superconducting electrode 115. As a result, the tunnel barrier 113 is not disposed on the sidewall 115b of the second superconducting electrode 115, which is different from the tunnel barrier 413 in FIG. 11.

In this example, the first superconducting electrode 111 is longer than the second superconducting electrode 115 along the X direction, and the first superconducting electrode 111 is partially covered by the tunnel barrier 113 and partially covered by the capping layer 117. It should be understood that the first superconducting electrode 111 may alternatively be as long as and aligned with the second superconducting electrode 115 along the X direction. While the first superconducting electrode 111 is shown to be disposed in the base layer 101, it should be understood that the first superconducting electrode 111 may alternatively be disposed above the base layer 101, with no layer in between, or with one or more layers in between.

In some preferred embodiments, the first superconducting electrode 111 and the second superconducting electrode 115 each independently include niobium, tantalum or aluminum. The tunnel barrier 113 includes tantalum nitride, aluminum nitride, tantalum oxide or aluminum oxide. The capping layer 117 includes nickel, copper or cobalt. The base layer 101 includes silicon or silicon oxide.

More generally, the first superconducting electrode 111 and the second superconducting electrode 115 can each independently include at least one selected from the group consisting of an elemental superconducting metal, a superconducting alloy and a superconducting nitride. Examples of the first superconducting electrode 111 and the second superconducting electrode 115 described below can be used individually or in any combination.

Examples of the elemental superconducting metal can include, but are not limited to, lead (Pb), lanthanum (La), tantalum (Ta), mercury (Hg), tin (Sn), indium (In), palladium (Pd), chromium (Cr), thallium (Tl), rhenium (Re), protactinium (Pa), thorium (Th), aluminum (Al), gallium (Ga), molybdenum (Mo), zinc (Zn), osmium (Os), zirconium (Zr), americium (Am), cadmium (Cd), ruthenium (Ru), titanium (Ti), uranium (U), hafnium (Hf), iridium (Ir), beryllium (Be), tungsten (W), platinum (Pt), lithium (Li), rhodium (Rh), yttrium (Y) and bismuth (Bi). Preferably, examples of the elemental superconducting metal can include Nb, Ta, Al, La, In, Cr, Zr, Ru and Ti. Preferably, examples of the elemental superconducting metal can include Nb, Ta and Al.

Examples of the superconducting alloy can include, but are not limited to, NbTi, WSi, NbZr, Nb₃Al, Nb₃Ge, Nb₃Sn and NbTi. Preferably, examples of the superconducting alloy can include NbTi, WSi, NbZr and NbTi. Preferably, examples of the superconducting alloy can include NbTi and WSi.

Examples of the superconducting nitride can include, but are not limited to, NbN, InN, TiN, ZrN, HfN, MoN and WN. Preferably, examples of the superconducting nitride can include NbN, InN, TiN and ZrN. Preferably, examples of the superconducting nitride can include NbN.

The tunnel barrier 113 can include at least one selected from the group consisting of a non-superconducting metal nitride, a non-superconducting metal oxide and a non-superconducting metal carbide. Examples of the tunnel barrier 113 described below can be used individually or in any combination.

Examples of the non-superconducting metal nitride can include, but are not limited to, tantalum nitride, aluminum nitride, copper nitride and gallium nitride. Preferably, examples of the non-superconducting metal nitride can include tantalum nitride and aluminum nitride.

Examples of the non-superconducting metal oxide can include, but are not limited to, tantalum oxide, aluminum oxide, zinc oxide and cobalt oxide. Preferably, examples of the non-superconducting metal oxide can include tantalum oxide and aluminum oxide.

Examples of the non-superconducting metal carbide can include, but are not limited to, tantalum carbide and aluminum carbide.

The capping layer 117 can include one selected from the group consisting of a non-superconducting metal and a non-superconducting nitride. Examples of the capping layer 117 described below can be used individually or in any combination.

Examples of the non-superconducting metal can include, but are not limited to, nickel, copper and cobalt.

Examples of the non-superconducting nitride can include, but are not limited to, tantalum nitride, aluminum nitride, copper nitride and gallium nitride. Preferably, the non-superconducting nitride can include tantalum nitride and aluminum nitride.

The base layer 101 can include a substrate or a layer (e.g. an oxide layer) formed over a substrate. “Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, the substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Some examples described in the present disclosure have subscripts to indicate the number or ratio of atoms. For instance, Nb₃Al indicates the number of Nb to the number of Al has a ratio of 3. Some examples described in the present disclosure have no subscripts e.g. HfN, WN, TaN and SiGe. It should be understood that such notations do not necessarily mean that the ratio of corresponding atom numbers is 1:1. For instance, HfN can include Hf₃N₄, WN can include W₂N₃ and W₃N₄, TaN can include Ta₃N₅, and SiGe can include SiₓGe₁₋ₓ (0<x<1), as a skilled artisan would understand. In other words, when there are no subscripts, the ratio of corresponding atom numbers may be 1:1 or may not be 1:1, in which case the subscripts are omitted for simplicity purposes.

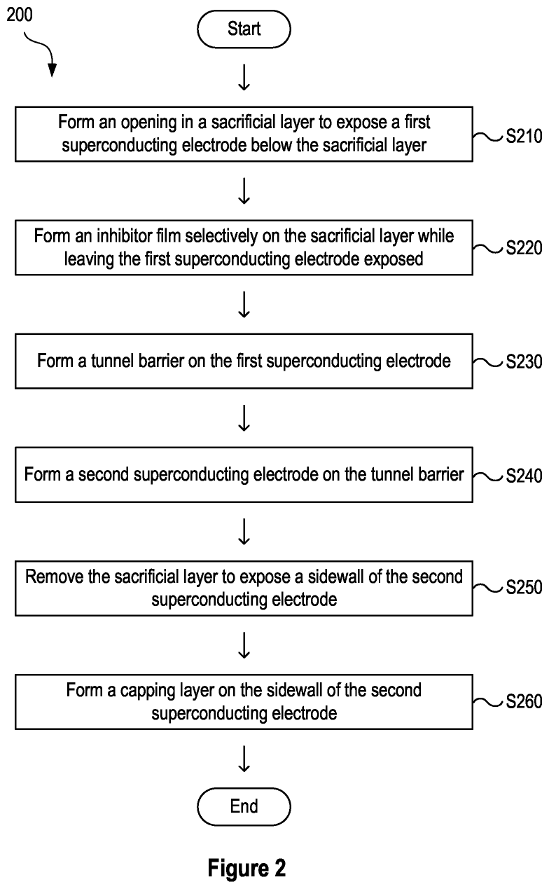

FIG. 2 shows a flow chart of a process 200 for manufacturing a semiconductor device, such as the semiconductor device 100 and the like, in accordance with some embodiments of the present disclosure. At step S210, an opening is formed in a sacrificial layer to expose a first superconducting electrode below the sacrificial layer. At step S220, an inhibitor film is formed selectively on the sacrificial layer while leaving the first superconducting electrode exposed. At step S230, a tunnel barrier is formed on the first superconducting electrode. At step S240, a second superconducting electrode is formed on the tunnel barrier. At step S250, the sacrificial layer is removed to expose a sidewall of the second superconducting electrode. At step S260, a capping layer is formed on the sidewall of the second superconducting electrode.

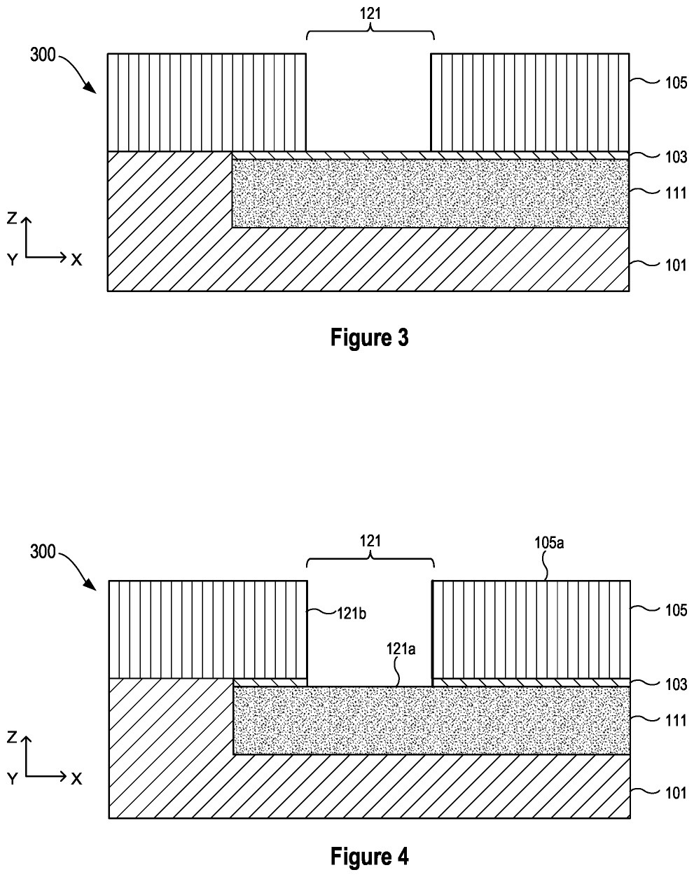

FIGS. 3, 4, 5, 6, 7, 8, 9 and 10 show vertical cross-sectional views of a semiconductor device 300 at various intermediate steps of manufacturing, in accordance with some embodiments of the present disclosure. Embodiments of the semiconductor device 300 in FIGS. 3-10 can be similar to embodiments of the semiconductor device 100 in FIG. 1. Note that similar or identical components are labeled with similar or identical numerals unless specified otherwise. Descriptions have been provided above and will be omitted for simplicity purposes.

As shown in FIG. 3, the semiconductor device 300 includes the base layer 101 and the first superconducting electrode 111. The semiconductor device 300 can also include a metal oxide layer 103 formed over the first superconducting electrode 111. The semiconductor device 300 can further include a sacrificial layer 105 formed over the base layer 101 and the metal oxide layer 103. The sacrificial layer 105 can be patterned and etched to form an opening 121. As a result, the metal oxide layer 103 is exposed by the opening 121.

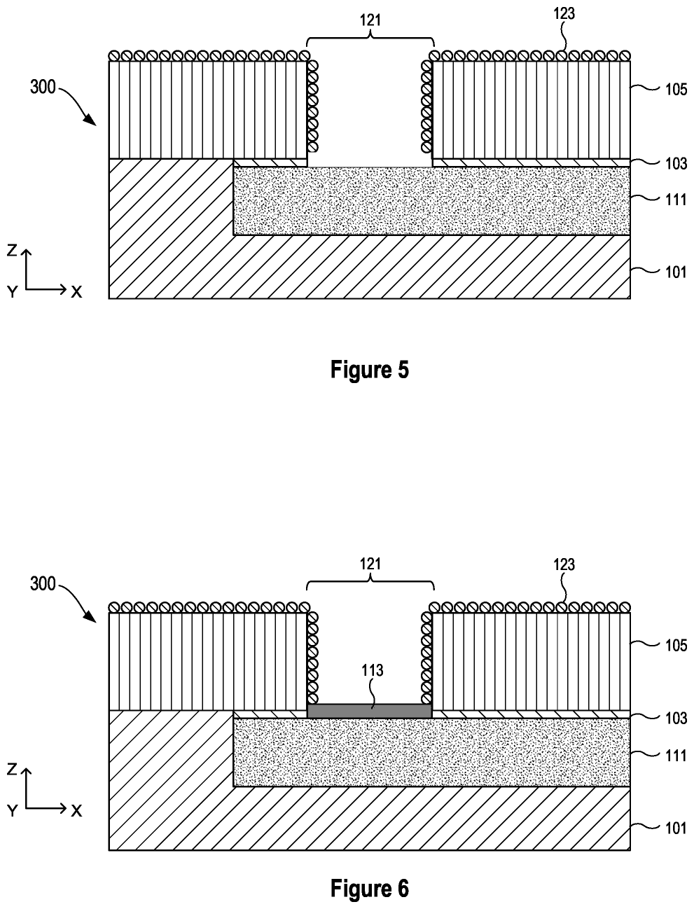

In some embodiments, the sacrificial layer 105 includes a low-k dielectric. Examples of the low-k dielectric can include, but are not limited to, silicon oxide, silicon nitride, carbon-doped oxide (SiCOH) and silicon oxynitride. Examples of the sacrificial layer 105 described herein can be used individually or in any combination. Examples of the sacrificial layer 105 are not particularly limited if the sacrificial layer 105 can enable selective chemistry in e.g. FIGS. 4 and 5 as will be described in detail later.

The metal oxide layer 103 can include a metal oxide corresponding to the first superconducting electrode 111. For instance, when the first superconducting electrode 111 includes niobium, tantalum or aluminum, the metal oxide layer 103 can respectively include niobium oxide, tantalum oxide or aluminum oxide. When the first superconducting electrode 111 includes niobium nitride, the metal oxide layer 103 can include niobium oxide. When the first superconducting electrode 111 includes a superconducting alloy (e.g. NbTi), the metal oxide layer 103 can include oxides (e.g. niobium oxide and titanium oxide) of metal elements of the superconducting alloy. The metal oxide layer 103 can include a native oxide layer, a deposited oxide layer, an in-situ grown oxide layer or a combination thereof. Additionally or alternatively, the metal oxide layer 103 can include a metal oxide that does not correspond to the first superconducting electrode 111.

In FIG. 4, the metal oxide layer 103 is etched so that the first superconducting electrode 111 is exposed by the opening 121. The opening 121 has a sidewall 121b and a bottom 121a. FIGS. 3 and 4 can be accomplished by two separate etching processes or a single etching process.

In FIG. 5, an inhibitor film 123 is formed selectively on the sacrificial layer 105 while leaving the first superconducting electrode 111 exposed. The inhibitor film 123 may or may not be formed to cover side surfaces of the metal oxide layer 103. The inhibitor film 123 can be formed by area-selective deposition using vapor deposition techniques such as atomic layer deposition (ALD), chemical vapor deposition (CVD), physical vapor deposition (PVD) and the like. The inhibitor film 123 can include a single layer of atoms such as a self-assembled monolayer (SAM) or include multiple layers of atoms.

The inhibitor film 123 can include at least one selected from the group consisting of a halogen-containing silane, a boron-containing molecule, a nitrogen-containing silane and an organic molecule. Examples of the inhibitor film 123 described below can be used individually or in any combination.

Examples of the halogen-containing silane can be represented by a formula of SiₙRₐX_{b}. n is an integer of 1 to 16, preferably 1 to 8, preferably 1, 2, 3 or 4. a is an integer of 1 or more, e.g. 1, 2, 3 or more. b is an integer of 1 or more, e.g. 1, 2, 3 or more. x+y=2n+2. R is a hydrogen atom or an alkyl group, linear or branched, having a carbon atom number of 1 to 20, preferably 2 to 16, preferably 3 to 12, preferably 4 to 8. When a is 2 or more, each R is independently a hydrogen atom or an alkyl group. X is Cl, Br or F, preferably Cl or F, preferably Cl. When b is 2 or more, each X is independently Cl, Br or F. Examples of the halogen-containing silane can include, but are not limited to, monochlorosilane (H₃SiCl), dichlorosilane, tetrachlorosilane, pentachlorodisilane, hexachlorodisilane, octachlorotrisilane, methyltrichlorosilane, dimethyldichlorosilane, chlorotrimethylsilane, ethyltrichlorosilane, butyl trichlorosilane, octyl trichlorosilane, dodecyl trichlorosilane, octadecyl trichlorosilane, difluorosilane, methyltrifluorosilane and fluorotrimethylsilane. Preferably, examples of the halogen-containing silane can include methyltrichlorosilane, dimethyldichlorosilane, chlorotrimethylsilane, ethyltrichlorosilane, butyl trichlorosilane, octyl trichlorosilane, dodecyl trichlorosilane and octadecyl trichlorosilane.

Examples of the boron-containing molecule can include, but are not limited to, (dimethylphenylsilyl)boronic acid pinacol ester and 3-pyridinylboronic acid.

Examples of the nitrogen-containing silane can include, but are not limited to, N,N-dimethyltrimethylsilylamine (TMSDMA), (3-aminopropyl)trimethoxysilane and (3-aminopropyl)triethoxysilane. Preferably, the nitrogen-containing silane can include TMSDMA.

Examples of the organic molecule can include, but are not limited to, pyridine.

In FIG. 6, the tunnel barrier 113 is selectively formed on the first superconducting electrode 111, relative to the inhibitor film 123. The tunnel barrier 113 can be formed by area-selective deposition using vapor deposition techniques such as ALD, CVD, PVD and the like. The inhibitor film 123 can suppress, inhibit and/or block the area-selective deposition of the tunnel barrier 113, therefore leading to area selectivity.

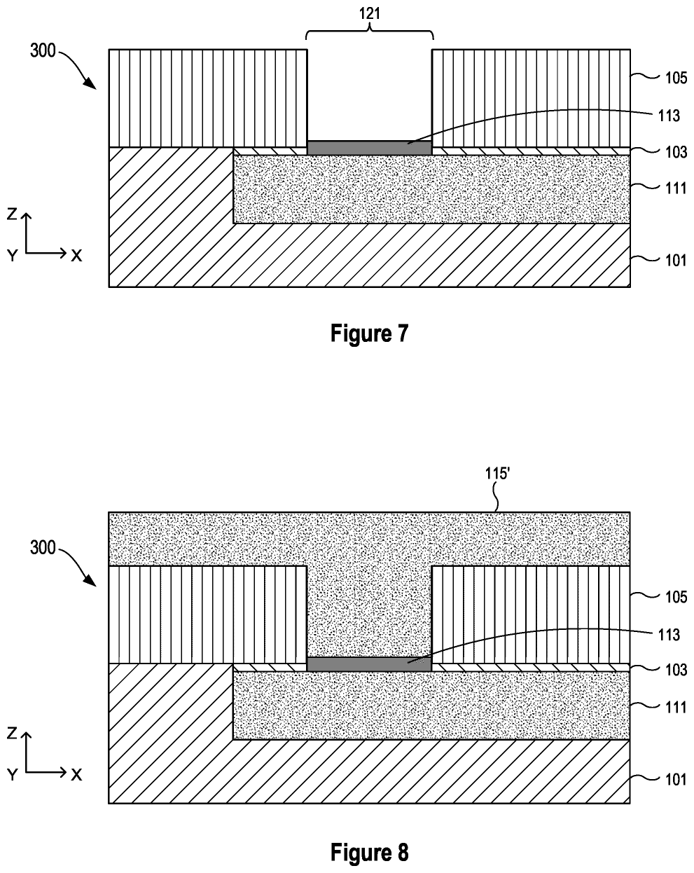

In FIG. 7, the inhibitor film 123 is removed from the sacrificial layer 105.

In FIG. 8, a superconducting material 115′ is formed in the opening 121, optionally resulting in an overburden of the superconducting material 115′ over the sacrificial layer 105. The superconducting material 115′ can be formed by vapor deposition techniques such as ALD, CVD, PVD and the like.

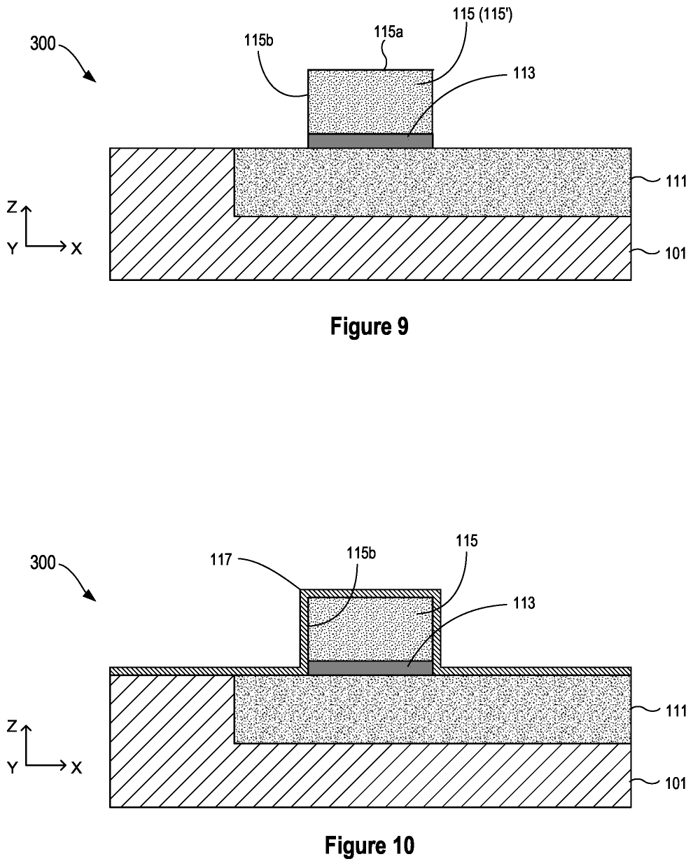

In FIG. 9, the overburden of the superconducting material 115′ is removed so that a remaining portion of the superconducting material 115′ forms the second superconducting electrode 115. The sacrificial layer 105 can be removed, for example by a wet etch process using hydrofluoric acid (HF) or dilute hydrofluoric acid (dHF). As a result, the top surface 115a and the sidewall 115b are exposed.

In some embodiments, a chemical-mechanical polishing or planarization (CMP) process, a reactive ion etch (RIE) process and/or the like can be executed to remove the overburden of the superconducting material 115′, followed by wet etch or dry etch to remove silicon oxide of the sacrificial layer 105.

In FIG. 10, the capping layer 117 is formed on the sidewall 115b and the top surface 115a of the second superconducting electrode 115. The capping layer 117 can also be formed to partially cover the top surface of the first superconducting electrode 111. The capping layer 117 can be formed by vapor deposition techniques such as ALD, CVD, PVD and the like. As a result, the semiconductor device 300 can become the semiconductor device 100.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of manufacturing a semiconductor device, the method comprising:
forming an opening in a sacrificial layer to expose a first superconducting electrode below the sacrificial layer;
forming an inhibitor film selectively on the sacrificial layer while leaving the first superconducting electrode exposed;
forming a tunnel barrier on the first superconducting electrode;
forming a second superconducting electrode on the tunnel barrier;
removing the sacrificial layer to expose a sidewall of the second superconducting electrode; and
forming a capping layer on the sidewall of the second superconducting electrode.

2. The method of claim 1, wherein the forming the opening comprises:
etching through the sacrificial layer and a metal oxide layer that is positioned between the sacrificial layer and the first superconducting electrode.

3. The method of claim 1, further comprising:
after the forming the tunnel barrier, depositing a superconducting material in the opening, resulting in an overburden of the superconducting material over the sacrificial layer; and
removing the overburden of the superconducting material so that a remaining portion of the superconducting material forms the second superconducting electrode.

4. The method of claim 1, wherein:
the removing the sacrificial layer also exposes a top portion of the first superconducting electrode, and
the capping layer covers the top surface of the second superconducting electrode and the top portion of the first superconducting electrode.

5. The method of claim 1, wherein:
the first superconducting electrode and the second superconducting electrode each independently comprise one selected from the group consisting of an elemental superconducting metal, a superconducting alloy and a superconducting nitride.

6. The method of claim 5, wherein:
the elemental superconducting metal includes niobium (Nb), tantalum (Ta), aluminum (Al) or a combination thereof,
the superconducting alloy includes NbTi, WSi or a combination thereof, and
the superconducting nitride includes NbN.

7. The method of claim 1, wherein:
the inhibitor film comprises one selected from the group consisting of a halogen-containing silane, a boron-containing molecule, a nitrogen-containing silane and an organic molecule.

8. The method of claim 7, wherein:
the halogen-containing silane includes methyltrichlorosilane, dimethyldichlorosilane, chlorotrimethylsilane, ethyltrichlorosilane, butyl trichlorosilane, octyl trichlorosilane, dodecyl trichlorosilane, octadecyl trichlorosilane or a combination thereof,
the boron-containing molecule includes (dimethylphenylsilyl)boronic acid pinacol ester,
the nitrogen-containing silane includes N,N-dimethyltrimethylsilylamine (TMSDMA), and
the organic molecule includes pyridine.

9. The method of claim 1, wherein:
the tunnel barrier comprises one selected from the group consisting of a non-superconducting metal nitride, a non-superconducting metal oxide and a non-superconducting metal carbide.

10. The method of claim 9, wherein:
the non-superconducting metal nitride includes tantalum nitride, aluminum nitride or a combination thereof,
the non-superconducting metal oxide includes tantalum oxide, aluminum oxide or a combination thereof, and
the non-superconducting metal carbide includes tantalum carbide, aluminum carbide or a combination thereof.

11. The method of claim 1, wherein:
the capping layer comprises one selected from the group consisting of a non-superconducting metal and a non-superconducting nitride.

12. The method of claim 11, wherein:
the non-superconducting metal includes nickel, copper, cobalt or a combination thereof, and
the non-superconducting nitride includes tantalum nitride, aluminum nitride or a combination thereof.

13. The method of claim 1, wherein:
the sacrificial layer comprises one selected from the group consisting of silicon oxide, silicon nitride and silicon oxynitride.

14. The method of claim 1, wherein:
the second superconducting electrode is formed on the tunnel barrier so that the tunnel barrier is completely below the second superconducting electrode.

15. A semiconductor device, comprising:
a first superconducting electrode;
a tunnel barrier over the first superconducting electrode;
a second superconducting electrode over the tunnel barrier; and
a capping layer covering a top surface of the second superconducting electrode and a side surface of the second superconducting electrode.

16. The semiconductor device of claim 15, wherein:
the first superconducting electrode and the second superconducting electrode each independently comprise one selected from the group consisting of an elemental superconducting metal, a superconducting alloy and a superconducting nitride,
the tunnel barrier comprises one selected from the group consisting of a non-superconducting metal nitride, a non-superconducting metal oxide and a non-superconducting metal carbide, and
the capping layer comprises one selected from the group consisting of a non-superconducting metal and a non-superconducting nitride.

17. The semiconductor device of claim 16, wherein:
the first superconducting electrode and the second superconducting electrode each independently comprise an elemental superconducting metal,
the tunnel barrier comprises one selected from the group consisting of a non-superconducting metal nitride, a non-superconducting metal oxide and a non-superconducting metal carbide, and
the capping layer comprises a non-superconducting metal.

18. The semiconductor device of claim 17, wherein:
the first superconducting electrode and the second superconducting electrode each independently comprise niobium, tantalum, aluminum or a combination thereof,
the tunnel barrier comprises tantalum nitride, aluminum nitride, tantalum oxide, aluminum oxide, tantalum carbide, aluminum carbide or a combination thereof, and
the capping layer comprises nickel, copper, cobalt or a combination thereof.

19. The semiconductor device of claim 15, wherein:
the tunnel barrier is completely below the second superconducting electrode.

20. The semiconductor device of claim 15, wherein:
the first superconducting electrode is longer than the second superconducting electrode along a first lateral direction, and
the first superconducting electrode is partially covered by the tunnel barrier and partially covered by the capping layer.
